(19) United States
(12) Patent Application Publication
(10) Pub. No.: US 2012/0313240 A1
(43) Pub. Date: Dec. 13, 2012

(54) SEMICONDUCTOR PACKAGE AND FABRICATION METHOD THEREOF

(76) Inventors: Shih-Lian Cheng, Taoyuan County (TW); Tsung-Yuan Chen, Taoyuan County (TW)

(21) Appl. No.: 13/241,285

(22) Filed: Sep. 23, 2011

(30) Foreign Application Priority Data
Jun. 9, 2011 (TW) 100120095

(51) Int. Cl. H01L 23/498; H01L 21/60

(52) U.S. Cl. 257/737; 438/613; 257/E23.068; 257/E21.508

(57) ABSTRACT

A semiconductor package includes a substrate having a flip chip bonding area. A plurality of recessed bump pads are disposed in the flip chip bonding area. The substrate further includes a solder mask that covers a circuit area. A chip having a plurality of metal bumps is mounted in the flip chip bonding area. The metal bumps are respectively connected to the recessed bump pads. An underfill is filled into the gap between the substrate and the chip.

### BACKGROUND OF THE INVENTION

1. Field of the Invention

The present invention relates generally to a semiconductor package and fabrication method thereof, and more specifically, to a semiconductor package and fabrication method thereof that apply a substrate having embedded, recessed bump pads.

2. Description of the Prior Art

In current semiconductor packaging technology, high-efficiency electronic components are often connected together electrically and mechanically through solder bumps and underfill injected between solder bumps. For example, an IC flip chip is usually connected to a substrate by solder bumps. This connecting technology is called flip-chip (FC) bonding technology, and is considered a type of area array bonding, which is suited for application to high density package connecting processes.

The concept of the flip-chip (FC) bonding technology is to form solder bumps on electrode pads of an IC chip, reverse and put the IC flip chip on a packaging substrate having a plurality of bump pads, and after the bump pads are aligned with electrode pads of the IC chip, perform reflow solder bumps to connect the IC chip and the substrate through surface tension of the solder bumps when melted, such that the IC chip and the substrate bond with each other. Methods of forming solder bumps on the electrode pads of the IC chip include: solder printing and solder electroplating. No matter which method is applied to form solder bumps, the IC chip needs to be bonded to exposed bump pads through a solder resist opening (SRO) in a solder mask. In other words, limitations of the solder resist opening process (approaching 60±10 μm in current processes) limits formation of the solder bumps.

The difficulty of forming solder bumps to joint with bump pads of the substrate increases for fine pitch products because of permissible alignment accuracy and small pitch between bump pads. The small pitch between bump pads will lead to solder-climbing, decreasing process yield of the solder joint between IC chip and substrate. Further, because solder bumps are jointed to bump pads protruding from the surface of the substrate, overflowing leading to solder bridging between bump pads, resulting in short circuiting while performing the reflow treatment, will occur because of small pitch between bump pads.

### SUMMARY OF THE INVENTION

The present invention provides a substrate having embedded, recessed bump pads, a semiconductor package applying that substrate, and fabrication method thereof, to solve the said problems of the prior art.

The present invention provides a substrate having embedded, recessed bump pads including a core board, a dielectric layer, a second circuit pattern and a solder mask. The core board has a first circuit pattern on its surface. The dielectric layer is over the surface of the core board and covers the first circuit pattern. The second circuit pattern is embedded on a top surface of the dielectric layer, wherein the second circuit pattern includes at least an embedded traces on a circuit area and at least one recessed bump pad on a flip chip bonding area. A pre-solder layer is disposed on the recessed bump pad. A solder mask covers a circuit area outside the flip chip bonding area, wherein the embedded trace is inside the circuit area, and the recessed bump pad is located within the flip-chip bonding area.

The present invention provides a semiconductor package including a substrate, a flip chip and an underfill. The substrate includes a flip-chip bonding area having a plurality of embedded, recessed bump pads, and a circuit area having embedded traces. A pre-solder layer is disposed on each of the embedded, recessed bump pads. The substrate further includes a solder mask covering a circuit area out side of the flip chip bonding area. The active side of the flip chip includes a plurality of metal bumps connecting with the plurality of embedded, recessed bump pads in the flip-chip bonding area by flip chip method. The plurality of metal bumps bonds to the pre-solder layer on the embedded, recessed bump pads. The underfill fills into a gap in the flip-chip bonding area between the substrate and the flip chip.

The present invention provides a method of fabricating a substrate having embedded, recessed bump pads. A core board having a first circuit pattern on its surface is provided. A dielectric layer is laminated on the core board to cover the first circuit pattern. At least a trace trench and at least a bump pad trench are in a top surface of the dielectric layer. Filling the trace trenches and the bump pad trenches with metal, thereby forming a plurality of embedded traces and a plurality of embedded, recessed bump pads. A pre-solder layer is formed on each of the embedded, recessed bump pads. Covering the top surface of the dielectric layer with a solder mask, so that the solder mask can cover the embedded traces but exposing the bump pads.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a substrate having embedded, recessed bump pads according to one embodiment of the present invention.

FIG. 2A schematically depicts a cross-sectional view of a semiconductor package according to one embodiment of the present invention.

FIG. 2B schematically depicts a cross-sectional view of a semiconductor package according to one embodiment of the present invention.

FIGS. 3-11 schematically depict a processing flow chart of a substrate having embedded, recessed bump pads according to one embodiment of the present invention.

### DETAILED DESCRIPTION

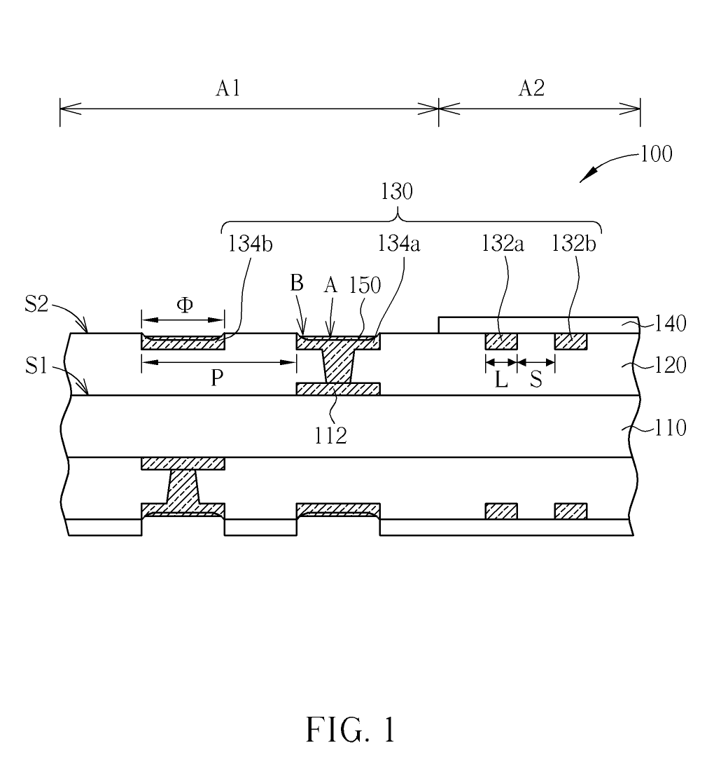

FIG. 1 schematically depicts a cross-sectional view of a substrate 100 having embedded, recessed bump pads according to one embodiment of the present invention. The substrate 100 is based on a core board 110, and multilayer circuits are gradually formed on its top and bottom sides by circuit build up technology. For simplicity, only the upper part of the substrate 100 (connected to a flip chip) is described in this embodiment, and the substrate 100 is a four-layer substrate as an example, but the substrate 100 can also be another multi-layer substrate.

To explicitly clarify the present invention, the numbers of embedded and recessed bump pads, trace trenches, bump pad trenches, circuit patterns or metal bumps disclosed in this embodiment are minimum numbers, so as to disclose the present invention clearly, but the numbers of the components are not limited. The numbers may be one or more than one, depending upon practical applications.

As shown in FIG. 1, the substrate 100 at least includes the core board 110, a first circuit pattern 112, a dielectric layer 120, a second circuit pattern 130 and a solder mask 140. The first circuit pattern 112 is disposed in the surface S1 of the core board 110, wherein the core board 110 may be glass-prepreg or other insulating materials. The first circuit pattern 112 may include conductive materials such as copper, but is not limited thereto.

The core board 110 may further include a plurality of conductive vias (not shown) to electrically connect circuit patterns on either side of the core board 110. The dielectric layer 120 is laminated on the surface S1 of the core board 110 and covers the first circuit pattern 112, wherein the materials of the dielectric layer 120 may be Ajinomoto Bond Film (ABF), but may also be other insulating materials.

The second circuit pattern 130 may be a buried circuit pattern, embedded in a top surface S2 of the dielectric layer 120. The second circuit pattern 130 may include at least an embedded trace and at least an embedded, recessed bump pad. For example, the second circuit pattern 130 may include two adjacent embedded traces 132a and 132b, and two adjacent embedded, recessed bump pads 134a and 134b. The process of forming the second circuit pattern 130 may be: forming at least a trench or via by laser ablating methods, and filling in conductive materials such as copper to form an embedded circuit by an electroplating process, without limitation thereto.

In a preferred embodiment, the embedded traces 132a, 132b and the embedded, recessed bump pads 134a, 134b of the second circuit pattern 130 are located on the same horizontal plane, and the embedded traces 132a, 132b and the embedded, recessed bump pads 134a, 134b are substantially flush with the top surface S2 of the dielectric layer 120. Otherwise, the solder mask 140 covers the embedded traces 132a, 132b but exposes the embedded, recessed bump pads 134a, 134b. In a preferred embodiment, the embedded, recessed bump pads 134a, 134b are all located in a flip-chip bonding area A1 and the solder mask 140 is located on a circuit area A2 outside of the flip-chip bonding area A1. Therefore, the solder mask 140 will not cover the embedded, recessed bump pads 134a, 134b.

The embedded, recessed bump pads 134a, 134b may be copper pads, but are not limited thereto. Each of the embedded, recessed bump pads 134a, 134b has a recessed area A surrounded by a protruding peripheral barrier B. A pre-solder layer 150 such as an immersion Sn layer, can be formed on the recessed area A by methods such as electroless plating, and the peripheral barrier B restrains the immersion Sn layer in the recessed area A. Due to the embedded, recessed bump pads 134a, 134b of the present invention having the recessed areas A and the peripheral barriers B, the overflowing of the pre-solder layer 150 can be avoided by controlling the recessed depth of the embedded, recessed bump pads 134a, 134b and the thickness of the pre-solder layer 150, such that regardless of whether the pre-solder layer 150 is recessed or flat/protruding, the problems of overflowing of the pre-solder layer 150 while a reflow treatment is performed can be avoided as the embedded, recessed bump pads 134a, 134b are central recessed bump pads.

The positions and sizes of the embedded, recessed bump pads 134a, 134b of the present invention are defined by trenches formed on the top surface S2 of the dielectric layer 120 by laser ablation technology, and conductive material are filled into the trenches, so that the flip-chip bonding area aren't covered by the solder mask to expose all the embedded, recessed bump pads 134a ,134b. By using laser ablation technology, the sizes and pitches of bump pads can be smaller than in the prior art, which defines the solder resist opening (SRO) by lithography processes in substrate fabrication.

The line width S of the embedded traces 132a, 132b formed by laser ablation can approach or be even less than 10 μm, the diameter of the embedded, recessed bump pads 134a, 134b can approach or be even less than 40 μm, and the pitch of the embedded, recessed bump pads 134a, 134b can approach or be even less than 80 μm. In a preferred embodiment, the ratio of line width L/line pitch S of the embedded traces 132a,132b can approach 10/10, and the ratio of diameter Φ/pitch P of the embedded, recessed bump pads 134a,134b can approach 30/60.

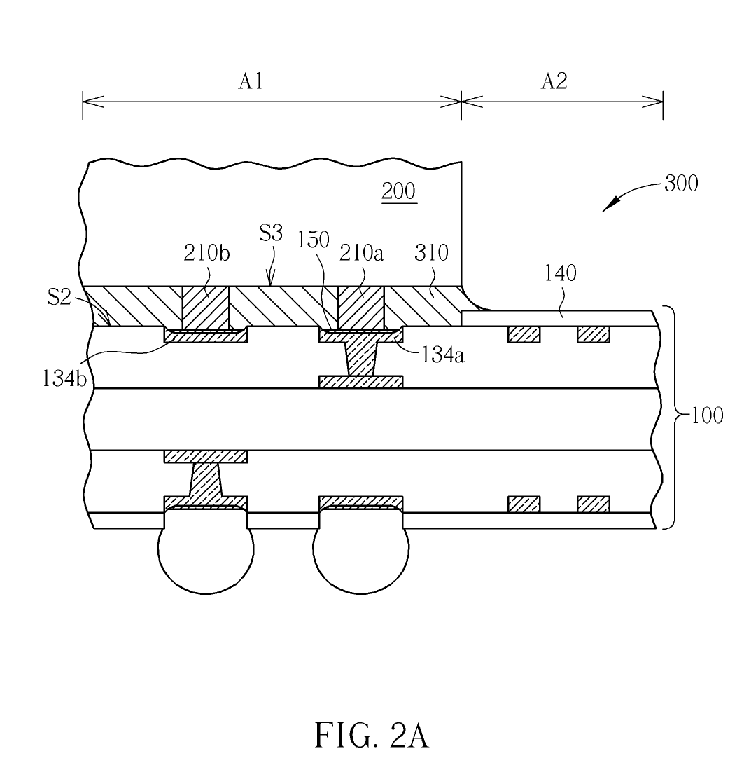

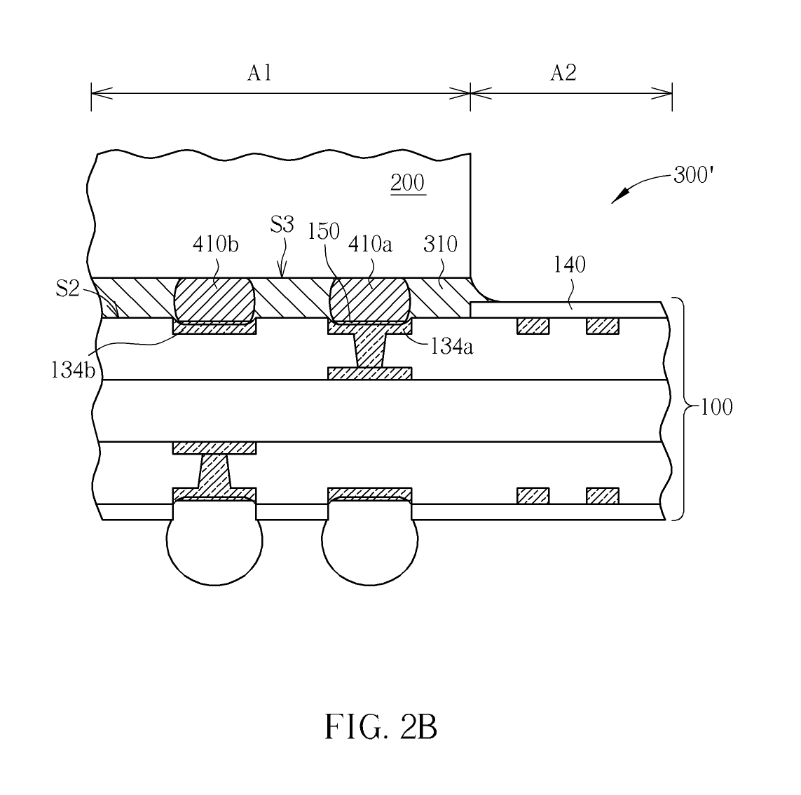

FIG. 2A schematically depicts a cross-sectional view of a semiconductor package according to one embodiment of the present invention. As shown in FIG. 2A, a flip chip 200 is bonded on a flip-chip bonding side of the aforesaid substrate 100, thereby composing a semiconductor package 300. The flip-chip bonding side of the aforesaid substrate 100 includes a flip-chip bonding area A1 having the embedded, recessed bump pads 134a, 134b disposed therein. A pre-solder layer 150 such as an immersion Sn layer, can be formed on the embedded, recessed bump pads 134a, 134b. The substrate 100 further includes a solder mask 140 covering a circuit area A2 outside of the flip-chip bonding area A1.

The active side S3 of the flip chip 200 includes metal bumps 210a, 210b respectively bonding with the pre-solder layer 150 on the embedded, recessed bump pads 134a, 134b of the substrate 100 by a flip chip method, wherein the material of the metal bumps 210a and 210b may be nickel, gold, silver, copper or their combinations. Underfill 310 is filled into a gap in the flip-chip bonding area A1 between the substrate 100 and the flip chip 200, to rigidly connect the substrate 100 and the flip chip 200.

In another embodiment of the present invention, the flip chip 200 and the embedded, recessed bump pads 134a, 134b of the substrate 100 may be bonded by solder bumps. As shown in FIG. 2B, the active side S3 of the flip chip 200 includes solder bumps 410a, 410b respectively bonding with the pre-solder layer 150 on the embedded, recessed bump pads 134a, 134b of the substrate 100 by the flip chip method, which may be paired with ref lowing treatments. A pre-solder layer 150 such as an immersion Sn layer, can be formed on the embedded, recessed bump pads 134a, 134b. Underfill 310 is filled into a gap in the flip-chip bonding area A1 between the substrate 100 and the flip chip 200, therefore composing a semiconductor package 300′.

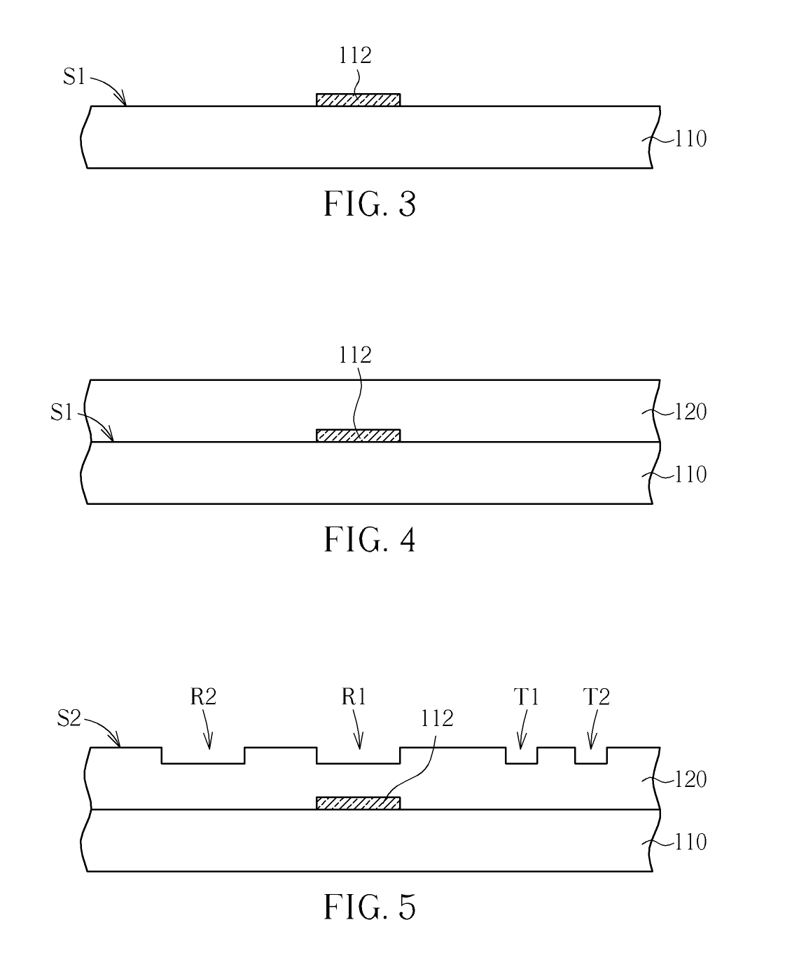

FIGS. 3-11 schematically depict a processing flow chart of a substrate having embedded, recessed bump pads according to one embodiment of the present invention. For simplicity, only the upper part of the substrate (connected to a flip chip) is described in this embodiment, and the substrate is a four-layer substrate as an example, but the substrate can also be another multi-layer substrate.

As shown in FIG. 3, a core board 110 is provided, having a first circuit pattern 112 formed on its surface S1, wherein the core board 110 maybe composed of glass-prepreg and further include a plurality of conductive vias (not shown). The first circuit pattern 112 may be made of conductive materials such as copper, but is not limited thereto. As shown in FIG. 4, a dielectric layer, such as Ajinomoto Bond Film (ABF) 120, is laminated on the core board 110 and covers the first circuit pattern 112.

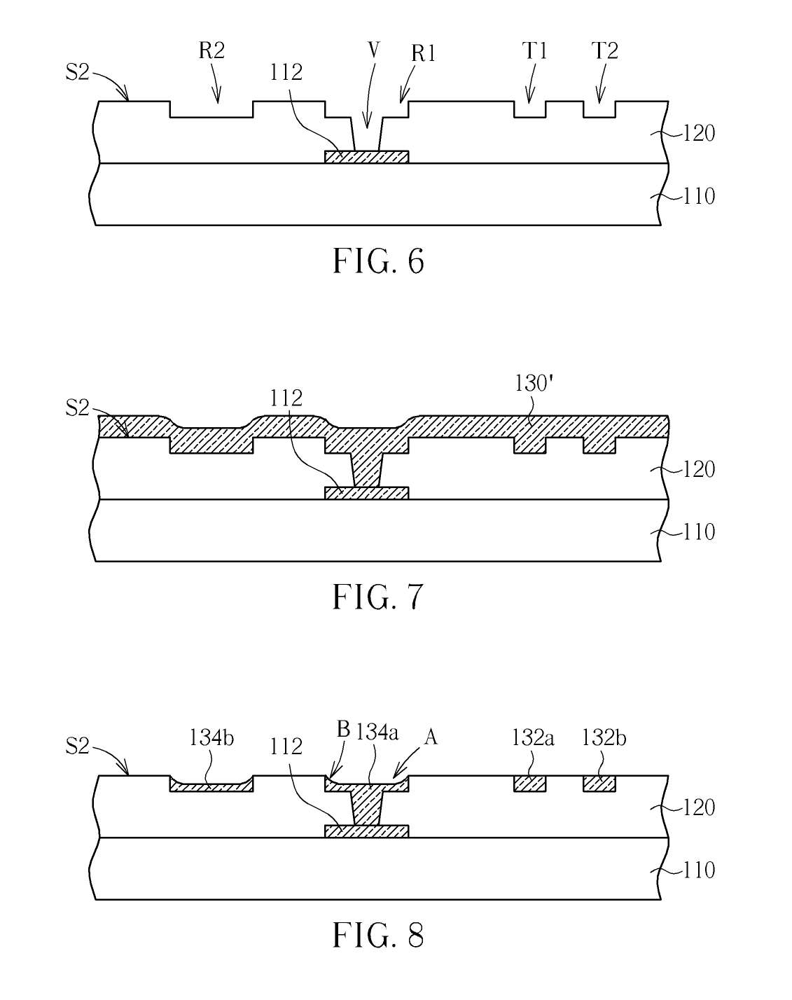

As shown in FIG. 5, bump pad trenches R1, R2 and trace trenches T1, T2 are formed in the top surface S2 of the dielectric layer 120 by methods such as laser ablation methods. As shown in FIG. 6, a via hole V passing through the dielectric layer 120 and connecting to the first circuit pattern 112 is formed at the bottom of the bump pad trenches R1 by laser ablation, so that the trace trenches T1, T2 and the bump pad trenches R1, R2 are formed in the top surface S2 of the dielectric layer 120. Numbers of the trace trenches T1, T2 and the bump pad trenches R1, R2 are not limited to those shown in the drawings, and depend upon practical needs.

As shown in FIG. 7, a metal layer 130′ is electroplated on the top surface S2 of the dielectric layer 120. The metal layer 130′ is also electroplated in the trace trenches T1, T2 and the bump pad trenches R1, R2. The recess of the bump pad trenches R1, R2 is larger than the recess of the trace trenches T1, T2, so that the metal layer 130′ electroplated on the bump pad trenches R1, R2 have recesses. In this embodiment, the electroplated metal may be copper, but it may be other materials.

As shown in FIG. 8, the metal layer 130′ is etched to respectively form the embedded traces 132a, 132b and the embedded, recessed bump pads 134a, 134b. Due to the width of the bump pad trenches R1, R2 being larger than the width of the trace trenches T1, T2, the bump pad trenches R1, R2 will not be completely filled with metal as the metal fills up the trace trenches T1, T2 after etching, therefore the recessed area A surrounded by the peripheral barrier B is formed in the bump pad trenches R1, R2.

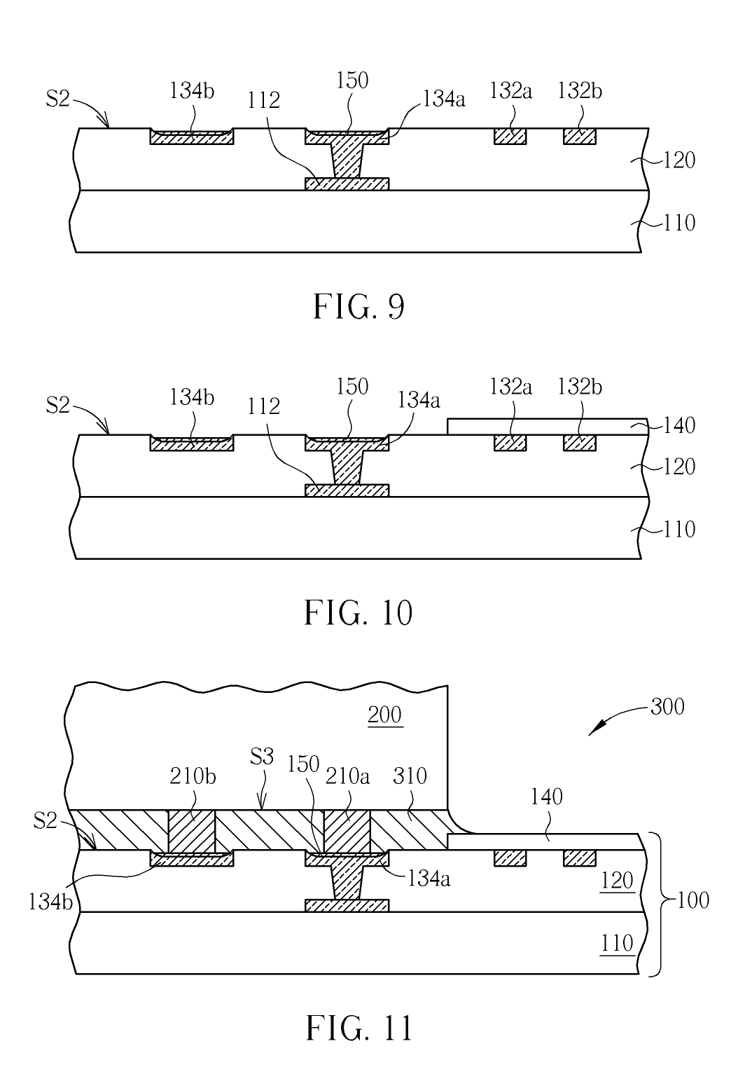

As shown in FIG. 9, a pre-solder layer 150 is formed in the recessed area A by chemical plating methods such as immersion Sn chemical plating. As shown in FIG. 10, the top surface S2 of the dielectric layer 120 is covered by a solder mask 140, to make the solder mask 140 cover the embedded traces 132a, 132b but expose the embedded, recessed bump pads 134a, 134b. In this time, the top surface of the embedded, recessed bump pads 134a, 134b may be lower than the top surface of the dielectric layer 120.

As shown in FIG. 11, the metal bumps 210a, 210b of the flip chip 200 are aligned and ref lowed to bond respectively to the embedded, recessed bump pads 134a, 134b, on which a pre-solder layer 150 such as an immersion Sn layer is formed, by the flip chip method, therefore a semiconductor package 300 is formed. The metal bumps 210a and 210b may be solder or copper, etc.

Above all, the present invention provides a substrate having embedded, recessed bump pads, a semiconductor package applying this substrate, and their fabrication methods. The forming method of the substrate having embedded, recessed bump pads may be: forming the bump pad trenches and the trace trenches by laser ablation methods, and then filling metal into the bump pad trenches and the trace trenches. In this way, the bump pad trenches and the trace trenches formed by laser ablation methods can have smaller sizes, thereby a precise substrate having refined bump pads and traces can be formed.

Otherwise, the recessed areas of the bump pads are surrounded by the peripheral barriers, thus the embedded, recessed bump pads having the peripheral barriers can avoid immersion Sn or solder balls formed on the recessed areas from overflowing, thereby avoiding short circuiting. In the embodiment in which the solder balls replace the metal bumps (as shown in FIG. 2B), due to the present invention applying the embedded, recessed bump pads, the semiconductor package of the present invention has advantages compared with the prior art, such as thinner thickness, and lower opportunity of solder balls connecting to each other.

In detail, the advantages of the present invention include: (1) the overflowing of the immersion Sn layer can be avoided by controlling the recessed depth of the embedded, recessed bump pads and the thickness of the immersion Sn layer, thereby regardless of whether the immersion Sn layer is recessed or flat/protruding, the problems of overflowing of the immersion Sn layer while a reflow treatment is performed can be avoided as the embedded, recessed bump pads have central recessed bump pads; and (2) by using laser ablation and laser-embedded technologies, the sizes and pitches of bump pads can be smaller than the prior art, which defines the solder resist opening (SRO) by lithography processes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A substrate, comprising:
a core board having a first circuit pattern on its surface;
a dielectric layer over the surface of the core board and covering the first circuit pattern;
a second circuit pattern embedded in a top surface of the dielectric layer, the second circuit pattern comprising a plurality of embedded traces and a plurality of embedded, recessed bump pads, wherein the embedded, recessed bump pads are disposed within a flip-chip bonding area;
a pre-solder layer on each of the embedded, recessed bump pads; and
a solder mask disposed outside the flip-chip bonding area such that the embedded, recessed bump pads inside the flip-chip bonding area are exposed.

2. The substrate according to claim 1 wherein the embedded traces and the embedded, recessed bump pads are substantially on a same horizontal plane that is in parallel with the top surface of the dielectric layer.

3. The substrate according to claim 1 wherein each of the embedded, recessed bump pads has a recessed area.

4. The substrate according to claim 1 wherein the pre-solder layer comprises immersion Sn.

5. A semiconductor package, comprising:
a substrate having a flip chip bonding area thereon, a plurality of embedded, recessed bump pads disposed in the flip chip bonding area, and a solder mask covering a circuit area outside the flip chip bonding area, such that the embedded, recessed bump pads inside the flip-chip bonding area are exposed;
a pre-solder layer disposed on each of the embedded, recessed bump pads;
a flip chip having a plurality of metal bumps on its active side mounted in the flip chip bonding area, wherein the plurality of metal bumps bonds to the pre-solder layer on the embedded, recessed bump pads respectively; and
an underfill filled in a gap between the substrate and the chip within the flip chip bonding area.

6. The semiconductor package according to claim 5 wherein the substrate further comprises a plurality of embedded traces within the circuit area covered with the solder mask.

7. The semiconductor package according to claim 6 wherein the embedded, recessed bump pads and the embedded traces are embedded in a dielectric layer of the substrate, and the embedded traces and the embedded, recessed bump pads are substantially in a same horizontal plane that is in parallel with the top surface of the dielectric layer.

8. The semiconductor package according to claim 5 wherein the pre-solder layer comprises immersion Sn.

9. A method of fabricating a substrate, comprising:
providing a core board having a first circuit pattern on its surface;
laminating a dielectric layer on the core board to cover the first circuit pattern;
forming a plurality of trace trenches and a plurality of bump pad trenches in a top surface of the dielectric layer;
filling the plurality of trace trenches and the plurality of bump pad trenches with metal, thereby forming a plurality of embedded traces and a plurality of embedded, recessed bump pads, wherein the plurality of embedded, recessed bump pads are within a flip chip bonding area;
forming a pre-solder layer on each of the embedded, recessed bump pads; and
covering the top surface of the dielectric layer with a solder mask, wherein the solder mask is formed outside the flip chip bonding area, such that the embedded, recessed bump pads inside the flip-chip bonding area are exposed.

10. The method of fabricating a substrate according to claim 9 wherein after forming the plurality of bump pad trenches, the method further comprises forming a via hole in one of the bump pad trenches, wherein the via hole contacts the first circuit pattern.

11. The method of fabricating a substrate according to claim 9 wherein the plurality of trace trenches and the plurality of bump pad trenches are formed by laser ablation methods.

12. A semiconductor package, comprising:
a substrate having a flip chip bonding area thereon, a plurality of embedded, recessed bump pads disposed in the flip chip bonding area, and a solder mask covering a circuit area outside the flip chip bonding area, such that the embedded, recessed bump pads inside the flip-chip bonding area are exposed;
a pre-solder layer disposed on each of the embedded, recessed bump pads;
a flip chip having a plurality of solder bumps on its active side mounted in the flip chip bonding area, wherein the plurality of solder bumps bonds to the pre-solder layer on the embedded, recessed bump pads respectively; and
an underfill filled in a gap between the substrate and the chip within the flip chip bonding area.

13. The semiconductor package according to claim 12 wherein the substrate further comprises a plurality of embedded traces within the circuit area covered by the solder mask.

14. The semiconductor package according to claim 13 wherein the embedded, recessed bump pads and the embedded traces are embedded in a dielectric layer of the substrate, and the embedded traces and the embedded, recessed bump pads are substantially in a same horizontal plane that is in parallel with the top surface of the dielectric layer.

15. The semiconductor package according to claim 12 wherein the pre-solder layer comprises immersion Sn.
